(19) United States
(12) Patent Application Publication
(10) Pub. No.: US 2020/0366066 A1
(43) Pub. Date: Nov. 19, 2020

(54) LASER DIODE ARRAY FOR A PROJECTOR

(71) Applicant: CHRISTIE DIGITAL SYSTEMS USA, INC., Cypress, CA (US)

(72) Inventor: William Kennedy LANDLES, Toronto (CA)

(21) Appl. No.: 16/414,877

(22) Filed: May 17, 2019

(51) Int. Cl. H01S 5/40; H01S 5/022

(52) U.S. Cl. CPC H01S 5/4093; H01S 5/02288; H01S 5/02296

(57) ABSTRACT

A laser diode array for a projector is provided. The laser diode array includes a first subset of laser diode devices configured to emit a first wavelength. The laser diode array further includes a second subset of the laser diode devices. Each of the laser diode devices of the second subset comprises: a wavelength selective optical feedback laser diode configured to emit according to a gain curve that includes the first wavelength; and a notch filter configured to reflect a second wavelength of the gain curve into the wavelength selective optical feedback laser diode to cause the wavelength selective optical feedback laser diode to amplify the second wavelength, the second wavelength different from the first wavelength.

### BACKGROUND

Until recently, cinema projection systems have made use of arc-lamp technology as an illumination source. However, newer projection systems incorporate Red-Green-Blue (RGB) laser light sources due to reduced cost, when amortized over the lifetime of a projection system, as well as improved image quality, as compared to arc-lamps. However, such laser light sources generally suffer from, and/or cause speckling artefacts, for example at a screen upon which images formed from the laser light sources are projected.

### BRIEF DESCRIPTIONS OF THE DRAWINGS

For a better understanding of the various embodiments described herein and to show more clearly how they may be carried into effect, reference will now be made, by way of example only, to the accompanying drawings in which:

FIG. 1 depicts a side schematic view of laser diode array for a projector, according to non-limiting examples.

FIG. 2 depicts a perspective view of the laser diode devices of the laser diode array of FIG. 1, according to non-limiting examples.

FIG. 3A depicts a schematic view of a laser diode of first type used with the laser diode array of FIG. 1, according to non-limiting examples.

FIG. 3B depicts a schematic view of a laser diode of second type used with the laser diode array of FIG. 1, according to non-limiting examples.

FIG. 4 depicts a gain curve of the laser diode of the second type, and a reflectance curve of a notch filter of the laser diode of the second type, according to non-limiting examples.

FIG. 5 depicts a side view of laser diode array for a projector, according to alternative non-limiting examples.

FIG. 6 depicts a top view of a common window of the laser diode array of FIG. 5, according to alternative non-limiting examples.

FIG. 7 depicts a side view of laser diode array for a projector, according to alternative non-limiting examples.

FIG. 8 depicts a top view of a common window of a laser diode array, according to alternative non-limiting examples.

### DETAILED DESCRIPTION

Until recently, cinema projection systems have made use of arc-lamp technology as an illumination source. However, newer projection systems incorporate Red-Green-Blue (RGB) laser light sources due to reduced cost, when amortized over the lifetime of a projection system, as well as improved image quality, as compared to arc-lamps. However, such laser light sources generally suffer from, and/or cause speckling artefacts, for example at a screen upon which images formed from laser light sources are projected.

Furthermore, such laser light sources may generally include high power laser diode devices, arranged in arrays, which operate with a very narrow wavelength emission spectrum which is a major source of coherent interference leading to the generation of speckling artefacts.

To reduce speckling artefacts, optical diversity may be provided at an array of laser diode devices used as a light source for a projector and/or a projector system. One approach to introducing optical diversity is to pseudo-fill each of the three available RGB (red-green-blue) color bands with as many discrete laser emission wavelengths as possible (one laser per wavelength). Another approach to introducing optical diversity is to actively modify the operating temperature of each laser diode, for example using heaters integrated with an array of laser diodes, which can generate a shift in operating wavelengths of the laser diodes and so generate new wavelengths. However, both approaches may be costly and/or complex.

Currently, off the shelf free-running laser diode devices cannot provide the full range of wavelengths that would be required to implement a fully diverse high brightness system. The term free-running is used herein to refer to laser diode devices which emit light at a wavelength that is at a top and/or at a maximum of their gain curve (described in further detail below).

However, as described herein, using wavelength selective optical feedback (WSOF), the free-running wavelength of light emitted by a laser diode may be altered. For example, WSOF may be employed in commercially available laser diode devices to tune their wavelengths and/or narrow their linewidths. However, such WSOF laser diode devices are expensive and intended for demanding applications that require very precise control over wavelengths and/or linewidth, such as spectroscopy and fiber laser pumping, and hence make use of expensive volume Bragg gratings, diffraction gratings or external cavity optics to very precisely tune wavelengths, etc.

However, as wavelength requirements for a low speckle laser light source for a projector are less demanding than such applications, provided herein is a laser diode array for a projector and/or a projector system which includes laser diode devices and WSOF laser diode devices where the wavelength tuning is implemented using notch filters. Such a laser diode array is generally low cost, as compared to standard WSOF laser dioes that use more complicated tuning optics.

Indeed, an aspect of the present specification provides a laser diode array for a projector comprising: a first subset of laser diode devices configured to emit a first wavelength; and a second subset of the laser diode devices, each of the laser diode devices of the second subset comprising: a wavelength selective optical feedback laser diode configured to emit according to a gain curve that includes the first wavelength; and a notch filter configured to reflect a second wavelength of the gain curve into the wavelength selective optical feedback laser diode to cause the wavelength selective optical feedback laser diode to amplify the second wavelength, the second wavelength different from the first wavelength.

Such a laser diode array may be adapted to include further subsets of laser diode devices that emit further wavelengths. Regardless, with at least two wavelengths emitted, for example, in a given color band, the laser diode array as described herein provides optical diversity which may reduce and/or eliminate speckle artefacts as compared to laser diode arrays that emit at a single wavelength.

Furthermore, the human eye perceives color most efficiently at 555 nm which is experienced as green, while blue and red wavelength regions are perceived less efficiently. Furthermore, within each of three cinema RGB bands (e.g. red, green and blue bands defined by various cinematic specifications), there is enough bandwidth margin to ensure that a laser diode with an emission wavelength located at one edge of a band will have significantly different perceived brightness when compared to a similar laser diode whose emission wavelength places it at the opposite end of the same band. Hence, the beneficial to have wavelength diversity starting from a band edge which has the maximum perceived brightness. As such, the laser diode array as described herein may be adapted such that the wavelengths emitted by WSOF laser diodes are photopically shifted towards 555 nm relative to free-running laser diodes; such photopic shifting is described in further detail below.

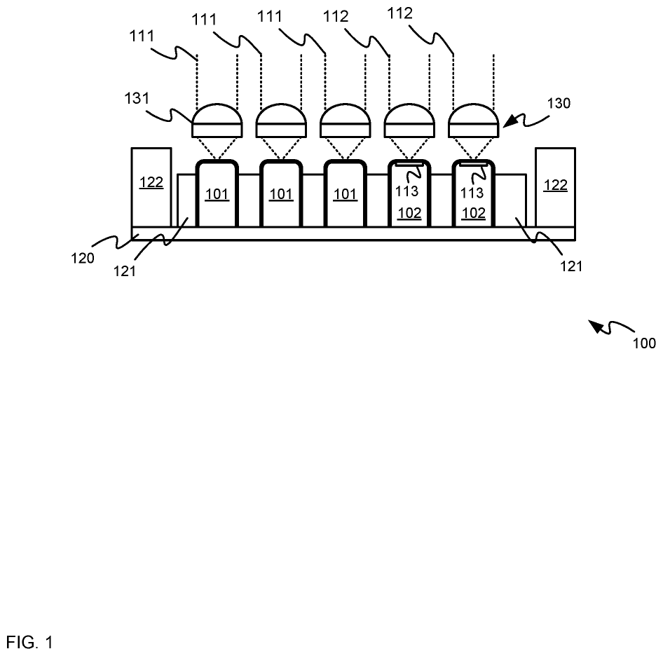

Attention is next directed to FIG. 1 which depicts a depicts a side schematic view of laser diode array 100 for a projector and/or a projector system. In other words, the laser diode array 100 is generally used as a light source for a projector and/or a projector system.

The laser diode array 100, interchangeably referred to hereafter as the array 100, comprises: a first subset of laser diode devices 101; and a second subset of laser diode devices 102. The first subset of laser diode devices 101 are configured to emit a first wavelength 111 of light, and the second subset of laser diode devices 102 are configured to emit a second wavelength 112 of light different from the first wavelength 111 of light. However, each of the laser diode devices 101, 102 generally emit a same general color of light, for example red or green or blue and/or any other color compatible with a projector and/or a projector system. However, while the wavelengths 111, 112 are of a same general color, the wavelengths 111, 112 are different from each other, though each of the wavelengths 111, 112 may be in a same color band (e.g. a red color band or a green color band or a blue color band, and the like) defined by any suitable projector and/or cinematic specification and/or standard; for example, such a specification and/or standard may define a range of wavelengths for a given color band. Such a range of wavelengths may be plus or minus about 1 nm to about 3 nm from a central wavelength and/or about 1 nm to about 5 nm from the central wavelength.

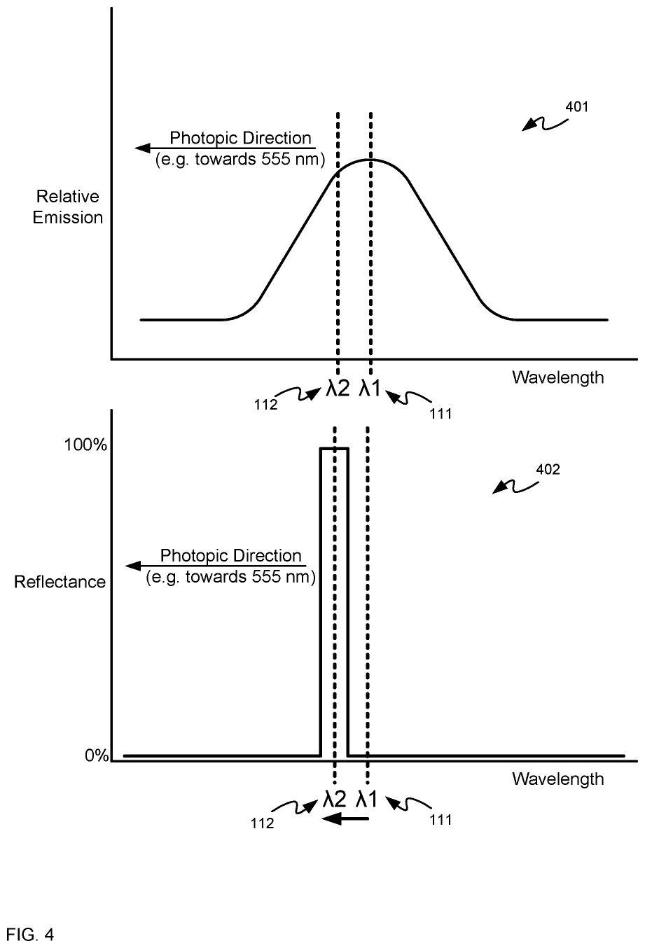

The wavelengths 111, 112 may alternatively be referred to as lasing wavelengths (e.g. wavelengths of coherent laser light emitted by the laser diode devices 101, 102), for example to distinguish the wavelengths 111, 112 from non-coherent light emitted by the laser diode devices 101, 102 (e.g. see the gain curve of FIG. 4).

In general, the laser diode devices 101 of the first subset include laser diode devices of a first type; for example, laser diode devices 101 may include, but are not limited to, off-the-shelf and/or free-running laser diode devices that emit light at the first wavelength 111 which may be, for example, a central wavelength of a range of wavelengths for a given color band and/or of a gain curve of a gain medium of a laser diode within the laser diode devices 101.

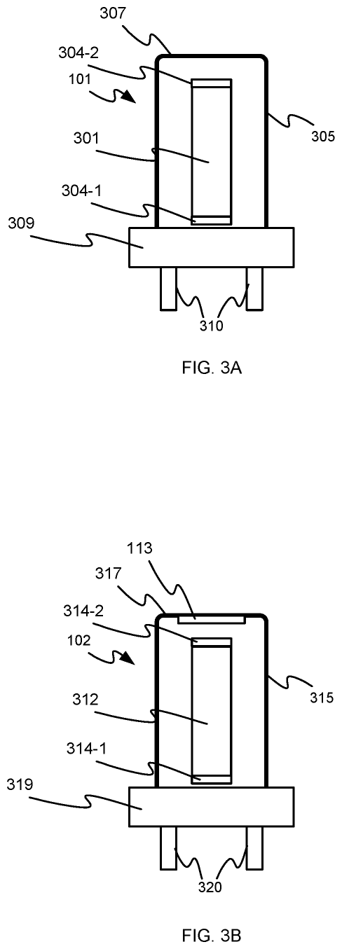

The laser diode devices 102 of the second subset are laser diode devices of a second type, for example that include: a wavelength selective optical feedback laser diode configured to emit according to a gain curve that includes the first wavelength 111; and a notch filter 113 configured to reflect the second wavelength 112 of the gain curve into the wavelength selective optical feedback laser diode to cause the wavelength selective optical feedback laser diode to amplify the second wavelength 112, the second wavelength 112 different from the first wavelength 111. The operation and structure of the laser diode devices 102 are described in more detail below with respect to FIG. 3B.

As depicted, the array 100 includes structural and/or alignment components. Such structural and/or alignment components may include a base 120 onto which the laser diode devices 101, 102 are mounted. While not depicted, the base 120 may include electrical connectors and/or sockets, and the like, for connecting with electrodes and/or wires of the laser diode devices 101, 102 (for example see FIG. 3A and FIG. 3B).

Such structural and/or alignment components may also include an alignment component 121, for example manufactured of metal and/or plastic, and the like, which holds the laser diode devices 101, 102 in alignment with each other, for example such that light from the laser diode devices 101, 102 is directed in the same direction. The alignment component 121 may comprise apertures through which a package and/or a base of the laser diode devices 101, 102 are inserted.

Such structural and/or alignment components may also include walls 122, and the like, that are may be located at least at opposite sides of the laser diode devices 101,102, the walls 122 to provide structural stability to the array 100 and/or to support other components of the array 100, for example optical components for directing light from the laser diode devices 101,102. As depicted, the alignment component 121 and the walls 122 extend from the base 120; in some examples, one or more of the base 120, the alignment component 121 and the walls 122 may be integrated with each other.

As depicted, the array 100 further includes a collimating lens array 130, each collimating lens 131 of the collimating lens array 130 configured to collimate light from a respective laser diode devices 101, 102 of the laser diode array 100. For example, as depicted, the collimating lens array 130 comprises a plurality of collimating lenses 131 in a one-to-one relationship with the laser diode devices 101, 102. While not depicted, the collimating lenses 131 may be mounted on a common support structure (e.g. a sheet of metal and/or plastic, and the like) which may be supported by the walls 122.

Further, as depicted, light of each of the wavelengths 111, 112 is emitted at an angle and/or as a cone from the laser diode devices 101, 102; the light of each of the wavelengths 111, 112 impinges on a respective collimating lens 131, which collimates the light of each of the wavelengths 111, 112 such that the light of each of the wavelengths 111, 112 is generally parallel as emitted from a respective collimating lens 131. Indeed, the light of each of the wavelengths 111, 112 may be directed by a respective collimating lens 131 to respective collection optics (not depicted), such as mirrors, prisms, other lenses, and the light, which collects and/or directs the light of each of the wavelengths 111, 112 to projection optics. The collection optics may also be configured to align light from the laser diode devices 101, 102, for example due to variations in the collimating lenses 131 and/or misalignment of the laser diode devices 101, 102.

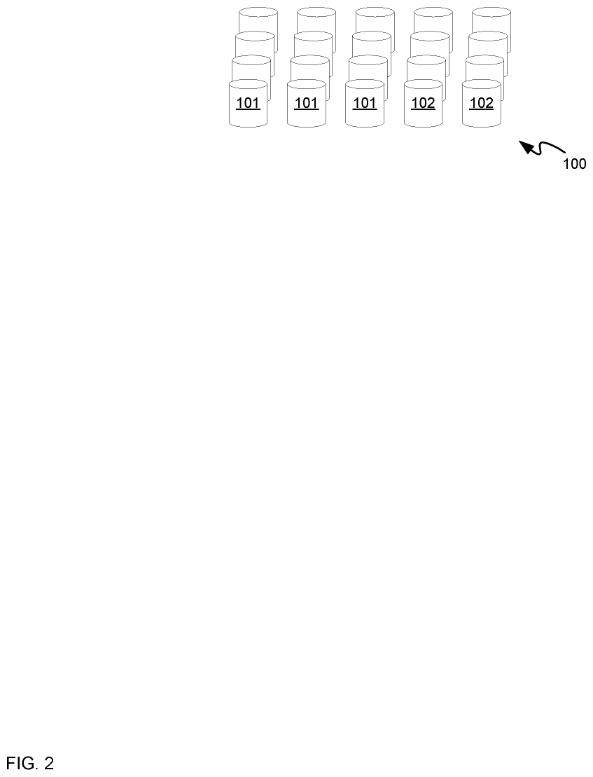

While FIG. 1 depicts five laser diode devices 101, 102, the array 100 may comprise any suitable number of laser diode devices 101, 102 in any suitable pattern and/or in any suitable ratio. For example, attention is directed to FIG. 2 which depicts a perspective view of the laser diode devices 101, 102 of the array 100 without other components of the array 100 (which are nonetheless understood to be present). As depicted, the array 100 of the laser diode devices 101, 102 comprises twenty laser diode devices arranged in 4×5 configuration (e.g. 4 rows and 5 columns, or vice versa); however, the array 100 of the laser diode devices 101, 102 may have any suitable number of rows and/or columns, and further the rows and/or columns may have different numbers of the laser diode devices 101, 102 (of either type of the laser diode devices 101, 102). Indeed, while the laser diode devices 101, 102 of a same type are depicted as adjacent to one another, the laser diode devices 101, 102 may be arranged in any suitable order (e.g. the laser diode devices 102 may be interspersed amongst the laser diode devices 101).

Furthermore, in some examples, each of the first subset of the laser diode devices 101, the second subset of the laser diode devices 102 may each comprise about one half of the laser diode devices 101, 102 of the laser diode array 100. In other words, the first subset of the laser diode devices 101 may make up about half of the laser diode devices of the array 100 and the second subset of the laser diode devices 102 may make up about the other half of the laser diode devices of the array 100. However, the laser diode devices 101, 102 of the laser diode array 100 may be provided in any suitable ratio and/or proportion to one another. Indeed, there may be as few as one laser diode device 101 in the first subset and/or one laser diode device 102 in the second subset.

Furthermore, as will be described below, while two subsets of the laser diode devices 101, 102 are depicted in FIG. 1 and FIG. 2, the array 100 may comprise a third subset of laser diode devices that emit light of a third wavelength, for example within the same color band as the wavelength 111, 112; indeed, the array 100 may comprise any suitable number of subsets of laser diode devices, each of which are configured to emit light of different wavelengths, and within the same color band, with a first subset comprising free-running laser diode devices (e.g. the laser diode devices 101), and the other subsets comprising laser diode devices that include WSOF laser diodes that emit light at respective wavelengths different from a wavelength of light emitted by the free-running laser diode devices.

The array 100 may comprise one of three arrays of laser diode devices; for example the array 100 may comprise an array of red laser diode devices, and may be provided with an array of green laser diode devices and an array of blue laser diode devices, each including any suitable number of respective laser diode devices, and each including at least two types of laser diode devices, similar to the array 100, but adapted for a respective color. The three arrays of laser diodes may collectively be used as an RGB light source for a projector and/or a projector system.

Attention is next directed to FIG. 3A which depicts a schematic diagram of a laser diode device 101 of the first subset and/or the first type. As depicted, the laser diode device 101 comprises a laser diode 301 that emits the light of the first wavelength 111 and hence includes a gain medium that emits light according to a gain curve (e.g. see FIG. 4) with suitable mirrors 304-1, 304-2 on either side of the gain medium. For example, the mirror 304-1 may have a reflectance of about 100% (e.g. across the wavelengths of the gain curve) while the mirror 304-2 may have a reflectance of less than 100% (e.g. between about 95% and about 99% across the wavelengths of the gain curve) and/or a non-zero transmittance (e.g. between about 1% and about 5% across the wavelengths of the gain curve) such that at least a portion of lased light from the gain medium exits the laser diode 301.

The laser diode device 101 further comprises a package 305 containing the laser diode 301, the package 305 including a respective package window 307 (e.g. adjacent the mirror 304-2), the respective package window 307 for emitting the light of the first wavelength 111 at an angle and/or a cone as depicted in FIG. 1. The respective package window 307 may include, but is not limited to, a lens, and the like, and is generally transparent to light emitted by the laser diode 301. The laser diode device 101 further comprises a base 309, to which the package 305 is attached, and electrodes 310 for receiving electrical power to cause the gain medium of the laser diode 301 to emit light. The base 309 may be mounted at the base 120 of the array 100 and/or the electrodes 310 may insert into a respective socket at the base 120 of the array 100, with any suitable power supply connecting to the electrode 310 to drive the laser diode 301.

Hence, in general, the depicted laser diode device 101 the first subset and/or the first type may comprise any suitable off-the-shelf and/or free-running laser diode device.

Attention is next directed to FIG. 3B which depicts a schematic diagram of a laser diode device 102 of the second subset and/or the second type. The components of the laser diode device 102 are similar to the components of the laser diode 101 the first subset and/or the first type. Such components may include: a laser diode 312, mirrors 314-1, 314-2, a package 315, a package window 317, a base 319 and electrodes 320, that are respectively substantially similar to the laser diode 301, mirrors 304-1, 304-2, the package 305, the package window 307, the base 309 and the electrodes 310, other than as described hereafter.

For example, the laser diode 312 generally comprises a wavelength selective optical feedback laser diode 312 that emits the light of the second wavelength 112 and hence includes a gain medium that emits light according to a gain curve (e.g. see FIG. 4) with suitable mirrors 314-1, 314-2 on either side of the gain medium. The gain medium of the laser diode 312 may be the same gain medium as that of the laser diode 301 such that each of the laser diodes 301, 312 has a similar gain curve. However, a lasing wavelength of each of the laser diodes 301, 312 may be different as described hereafter. Similarly, the mirror 314-1 may have a same reflectance as the 304-1 of the laser diode 301 (e.g. about 100%). However, in contrast to the laser diode 301, the mirror 314-2 may have a reflectance of between about 1% and about 10%; hence most of the light emitted by the gain medium exits the laser diode 312.

In further contrast to the laser diode device 101, the laser diode device 102 further comprises the notch filter 113 configured to reflect the second wavelength 112 of the gain curve into the wavelength selective optical feedback laser diode 312 to cause the wavelength selective optical feedback laser diode 312 to amplify the second wavelength 112, the second wavelength 112 different from the first wavelength 111. While the notch filter 113 is depicted at an inner side of the package window 317 (e.g. internal to the laser diode device 102) in other examples, the notch filter 113 may be at an outer side of the package window 317.

Regardless, in the depicted example, the notch filter 113 of each of the laser diode devices 102 of the second subset is located at a respective package window 317 of each of the laser diode devices 102 of the second subset.

In general, the notch filter 113 comprises layers of materials of different indices of refraction, for example metal oxides and the like, whose order, respective thicknesses and respective optical properties are selected to reflect light at the second wavelength 112 (and/or over a range that includes the second wavelengths 112) and otherwise be transparent to light of other wavelengths. In this manner, light at the second wavelength 112 emitted by the wavelength selective optical feedback laser diode 312 is reflected back into the wavelength selective optical feedback laser diode 312 to amplify the second wavelength 112. In other words, the wavelength selective optical feedback laser diode 312 amplifies the second wavelength 112 such that the second wavelength 112 is emitted by the laser diode device 102 as coherent light.

Attention is next directed to FIG. 4 which depicts a gain curve 401, which may be a gain curve of both of the laser diodes 301, 312, and a reflectance curve 402 of the notch filter 113.

The gain curve 401 generally shows relative emission of a gain material as a function of wavelength. As depicted the gain curve 401 has a Gaussian shape, and the like, has a peak at the first wavelength 111 (also labelled λ1 in FIG. 4). Hence, when the gain medium of the laser diode 301 emits light according to the gain curve 401, and the light is reflected back into the gain medium by the mirror 304-2, the gain medium amplifies light at the first wavelength 111 such that the first wavelength 111 is emitted by the laser diode device 101 as coherent light.

However, the gain curve 401 further includes light at the second wavelength 112 (also labelled λ2 in FIG. 4). Indeed, it is understood that a laser diode having the gain curve 401 emits light over a range of wavelengths, and a WSOF laser diode may be adapted to cause lasing at a wavelength (e.g. the second wavelength 112) other than the peak and/or the first wavelength 111 using the notch filter 113.

The reflectance curve 402 generally shows reflectance of the notch filter 113 as a function of wavelength. As depicted, the reflectance curve 402 of the notch filter 113 is selected to have a reflectance at the second wavelength 112 (and/or over a narrow range that includes the second wavelength 112) of between about 95% and about 99% (e.g. and/or a transmittance of between about 1% and about 5% the second wavelength 112), while the reflectance at other wavelengths, including the first wavelength 111, is about 0%. The range over which the notch filter 133 has a reflectance of between about 95% and about 99% may be, in some examples, plus or minus about 1 nm from the second wavelength 112.

Hence, the notch filter 113 reflects light at the second wavelength 112 back into the laser diode 312 (e.g. through the mirror 314-2) which amplifies the light at the second wavelength 112 to cause lasing at the second wavelength 112. Put another way, the notch filter 113 performs a similar functionality to volume Bragg gratings, diffraction gratings or external cavity optics of more standard WSOF laser diodes, but at less precise wavelength control, for example due to the non-zero width and/or range of the reflectance curve at the second wavelength 112.

As described above, the wavelengths 111, 112 may be of a same general color and within a color band of wavelengths defined by a projector and/or cinema specification and/or standard. Hence, the second wavelength 112 and/or the notch filter 113 may be selected such that the second wavelength 112 falls within a defined band of wavelengths (e.g. on either side of the first wavelength 111). For example, a difference between the second wavelength 112 and the first wavelength 111 may be in a range of about 1 nm to about 3 nm and/or in a range of about 1 nm to about 5 nm, with the reflectance properties of the notch filter 113 selected accordingly; however, the difference between the second wavelength 112 and the first wavelength 111 may be in any suitable range, with the reflectance properties of the notch filter 113 selected accordingly.

Furthermore, as described above, humans tend to be most sensitive to light at 555 nm. Hence, in the example depicted in FIG. 4, the wavelengths 111, 112 are assumed to be greater than 555 nm (e.g. the wavelengths 111, 112 may be perceived as red by a human), with a direction of 555 nm, with respect to the wavelengths 111, 112, indicated on both the gain curve 401 and the reflectance curve 402. Indeed, the direction of 555 nm, with respect to the wavelengths 111, 112 may be referred to as a photopic direction. However, if the wavelengths 111, 112 were less than 555 nm (e.g. perceived as blue by a human) the direction of 555 nm, with respect to the wavelengths 111, 112 would be in a direction opposite that depicted in FIG. 4. Regardless, a photopic direction as defined herein comprises a direction in which a wavelength shift occurs towards 555 nm. Similarly, photopic shifting and/or a second wavelength being photopically shifted with respect to a first wavelength is defined herein as the second wavelength being closer to 555 nm than the first wavelength. In such a manner the second wavelength may be perceived by a human as being brighter than the first wavelength when each are emitted at a similar intensity and/or luminance.

For example, as depicted in FIG. 4, the second wavelength 112 is photopically shifted, relative to the first wavelength 111, with the notch filter 113 selected accordingly. As such the second wavelength 112 is closer in value to 555 nm than the first wavelength 111, and hence the second wavelength 112 will be perceived by a human as being brighter than the first wavelength 111. In this manner, the brightness of the array 100 of the laser diode devices 101, 102 may be increased relative to an array of laser diode devices that include only the laser diode devices 101 (e.g. free-running laser diode devices 101 that emit light at the first wavelength 111).

In addition, as the array 100 of the laser diode devices 101, 102 include optically diverse wavelengths 111, 112, the array 100 of the laser diode devices 101, 102 will cause fewer speckle artefacts, and/or eliminate speckle artefacts, relative to an array of laser diode devices that include only the laser diode devices 101 (e.g. free-running laser diode devices 101 that emit light at the first wavelength 111).

While the examples of FIG. 1 and FIG. 3B depict the notch filter 113 at a package window of the laser diode devices 102 of the second subset, the notch filter 113 may alternatively be incorporated into a common window located adjacent respective package windows of the laser diode devices 102 of the second subset.

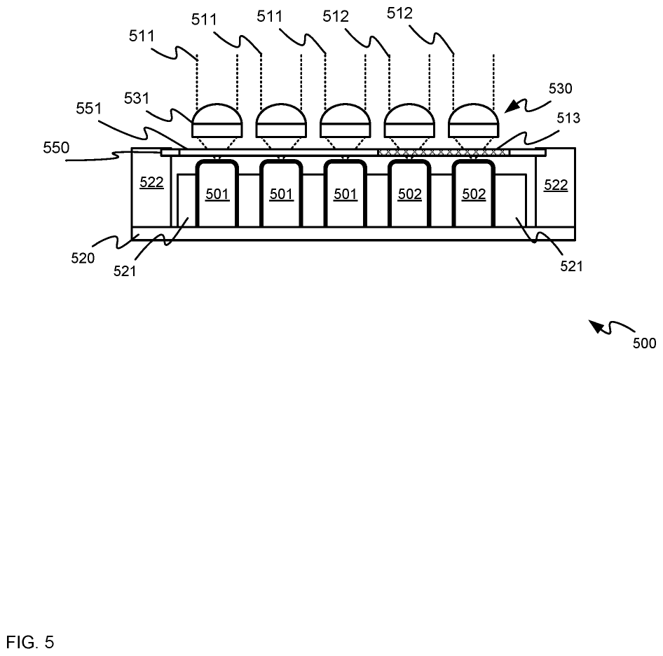

For example, attention is next directed to FIG. 5 which depicts a laser diode array 500 which is similar to the array 100, with like components having like numbers, however in a “500” series rather than a “100” series. Hence, the laser diode array 500 (interchangeably referred to hereafter as the array 500) comprises a first subset of laser diode devices 501 and a second subset of laser diode devices 502. The first subset of laser diode devices 501 are configured to emit a first wavelength 511 and second subset of laser diode devices 502 are configured to emit a second wavelength 512 different from the first wavelength 511. The wavelengths 511, 512 may be respectively similar to the wavelengths 111, 112, and/or the wavelengths 511, 512 may be different from the wavelengths 111, 112, for example in a different color band.

Each of the laser diode devices 502 of the second subset comprises: a wavelength selective optical feedback laser diode (e.g. not depicted, but similar to the laser diode 312) configured to emit according to a gain curve (e.g. similar to the gain curve 401) that includes the first wavelength 511; and a notch filter 513 (e.g. having a reflectance similar to the reflectance curve 402, but with the largest reflectance at the second wavelength 512) configured to reflect the second wavelength 512 of the gain curve into the wavelength selective optical feedback laser diode to cause the wavelength selective optical feedback laser diode to amplify the second wavelength 512.

As depicted, the array 500 further comprises: a base 520, an alignment component 521, walls 522, and a collimating lens array 530, comprising collimating lenses 531), which are respectively similar to the base 120, the alignment component 121, the walls 122, the collimating lens array 130, and the collimating lenses 131).

In contrast to the array 100, however, the notch filter 513 of each of the laser diode devices 502 of the second subset is located at a common window 550 located adjacent respective package windows of the laser diode devices 502 of the second subset. For example, the common window 550 may comprise a window made of any suitable transparent material (e.g. glass and/or plastic, and the like) with the notch filter 513 vacuum-deposited, and the like, onto a regions and/or regions adjacent the respective package windows of the laser diode devices 502. Hence, in these examples, the laser diode devices 502 include a respective region of the common window 550 that includes the notch filter 513. As depicted, the common window 550 is supported by the walls 522.

As depicted, the common window 550 includes a transparent region (and/or regions) 551 that is located adjacent respective package windows of the laser diode devices 501 of the first subset, the transparent region 551 being transparent at least to the first wavelength 511.

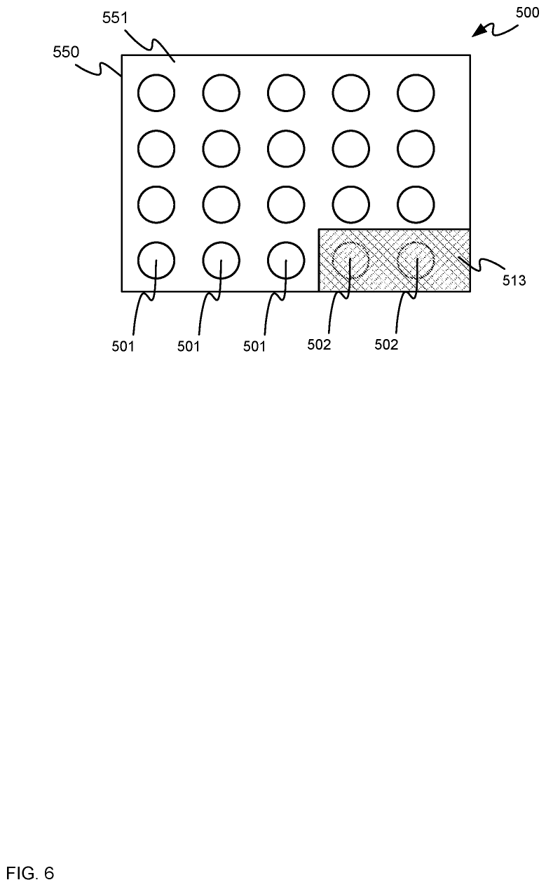

For example, attention is next directed to FIG. 6 which depicts a top view of the array 500 depicting the common window 550 and the laser diode devices 501, 502 (along with other laser diode devices of the array 500 depicted as circles), and without other components of the array 500 (which are nonetheless understood to be present). In the example of FIG. 6, the array 500 includes only two laser diode devices 502 and the notch filter 513 is located at the common window 550 (e.g. at a front or back of the common window 550) adjacent respective package windows of the laser diode devices 502. The remainder of the common window 550 comprises the transparent region 551, and similarly any laser diode device adjacent the transparent region 551 may be a laser diode device 501 that emits the first wavelength 511. However, while only two laser diode devices 502 are depicted, the array 500 may comprise any suitable number of laser diode devices 502 in any suitable ratio and/or location with respect to the laser diode devices 501.

The common window 550 comprises: a transparent region (and/or regions) 551 aligned with the respective package windows of the laser diode devices 501 of the first subset; and a notch filter region (and/or regions) aligned with the respective package windows of the laser diode devices 502 of the second subset, the notch filter regions each including the notch filter 513. In particular, when the laser diode devices 502 of the second subset are not adjacent to one another, the notch filter regions including the notch filter 513 may be distributed over the common window 550, each located adjacent a respective package window of a respective laser diode device 502 of the second subset.

As discussed above, the array 100 (and/or the array 500) may be adapted to include a third subset of laser diode devices that emit light at a third wavelength.

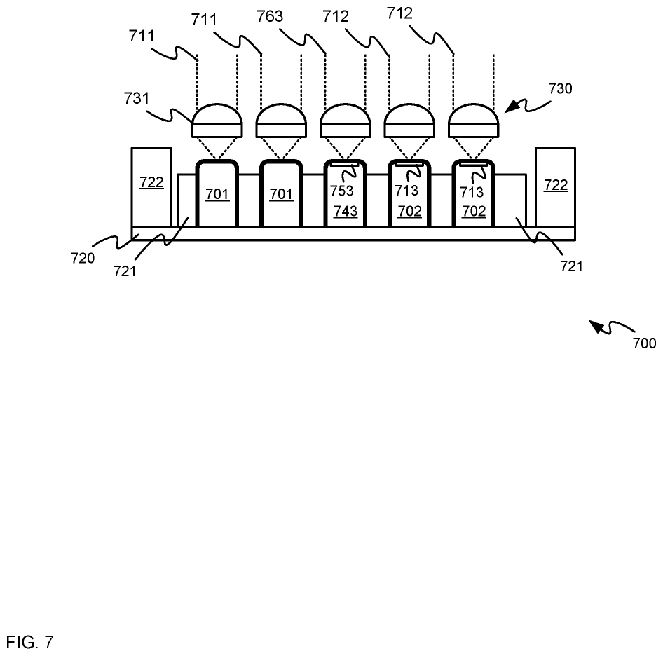

For example, attention is next directed to FIG. 7 which depicts a laser diode array 700 which is similar to the array 100, with like components having like numbers, however in a “700” series rather than a “100” series. Hence, the laser diode array 700 (interchangeably referred to hereafter as the array 700) comprises a first subset of laser diode devices 701 and a second subset of laser diode devices 702. The first subset of laser diode devices 701 are configured to emit a first wavelength 711 and second subset of laser diode devices 702 are configured to emit a second wavelength 712 different from the first wavelength 711. The wavelengths 711, 712 may be respectively similar to the wavelengths 111, 112, and/or the wavelengths 711, 712 may be different from the wavelengths 111, 112, for example in a different color band.

Each of the laser diode devices 702 of the second subset comprises: a wavelength selective optical feedback laser diode (e.g. not depicted, but similar to the laser diode 312) configured to emit according to a gain curve (e.g. similar to the gain curve 401) that includes the first wavelength 711; and a notch filter 713 (e.g. having a reflectance similar to the reflectance curve 402, but with the largest reflectance at the second wavelength 712) configured to reflect the second wavelength 712 of the gain curve into the wavelength selective optical feedback laser diode to cause the wavelength selective optical feedback laser diode to amplify the second wavelength 712. As depicted, the notch filter 713 is located at a respective package window of each of the laser diode devices 102 of the second subset.

As depicted, the array 700 further comprises: a base 720, an alignment component 721, walls 722, and a collimating lens array 730 (comprising collimating lenses 731), which are respectively similar to the base 120, the alignment component 121, the walls 122, and the collimating lens array 130 (and the collimating lenses 131).

Hence, the array 700 is substantially similar to the array 100. However, in contrast to the array 100, the array 700 further comprises: a third subset of laser diode devices 743, each of the laser diode devices 743 of the third subset comprising: a respective wavelength selective optical feedback laser diode (e.g. similar to the laser diode 312) configured to emit according to a respective gain curve (e.g. similar to the gain curve 401) that includes the first wavelength 711; and a respective notch filter 753 configured to reflect a third wavelength 763 of the respective gain curve into the respective wavelength selective optical feedback laser diode to cause the respective wavelength selective optical feedback laser diode to amplify the third wavelength 763, the third wavelength 763 different from each of the first wavelength 711 and the second wavelength 712. While only one laser diode device 743 is depicted, the array 700 may include any suitable number of laser diode devices 743. Indeed, in some examples, about a first third of the laser diode devices of the array 700 include the laser diode devices 701, about a second third of the laser diode devices of the array 700 include the laser diode devices 702, a last third of the laser diode devices of the array 700 include the laser diode devices 743. Put another way, each of the first subset of the laser diode devices 701, the second subset of the laser diode devices 702 and the third subset of the laser diode devices 743 may each comprise about one third of the laser diode devices 701, 702, 743 of the laser diode array 700.

Indeed, the laser diode devices 743 of the third subset are similar to the laser diode devices 702 of the second subset, but the notch filter 753 reflects light at the third wavelength 763 rather than the second wavelength 712. As such, the laser diode devices 743 emit light at the third wavelength 763, different from the wavelengths 711, 712, and a same general color as the wavelengths 711, 712, and/or in a same color band as the wavelengths 711, 712.

Indeed, the third wavelength 763 may be photopically shifted, relative to the first wavelength 711 such that each of the wavelengths 712, 763 are photopically shifted, relative to the first wavelength 711.

Further, a difference between the second wavelength 712 and the first wavelength 711 may the same as the difference between the second wavelength 112 and the first wavelength 111 described above. Similarly, a difference between the third wavelength 763 and the first wavelength 711 may be in a range of about 1 nm to about 3 nm and/or in a range of about 1 nm to about 5 nm, with the reflectance properties of the notch filter 753 selected accordingly; however, the difference between the third wavelength 763 and the first wavelength 111 may be in any suitable range, with the reflectance properties of the notch filter 753 selected accordingly. Regardless, the wavelengths 711, 712, 763 are understood to be different from one another.

As depicted in FIG. 7, the notch filter 713 and the respective notch filter 753 of the second subset of the laser diode devices 702 and the third subset of the laser diode devices 743 are located at a respective package window of each of the laser diode devices 702, 743 of the second subset and the third subset. However, the array 700 may be adapted to include a common window similar to the common window 550 with the notch filters 713, 753 located at the common window instead of at a respective package window.

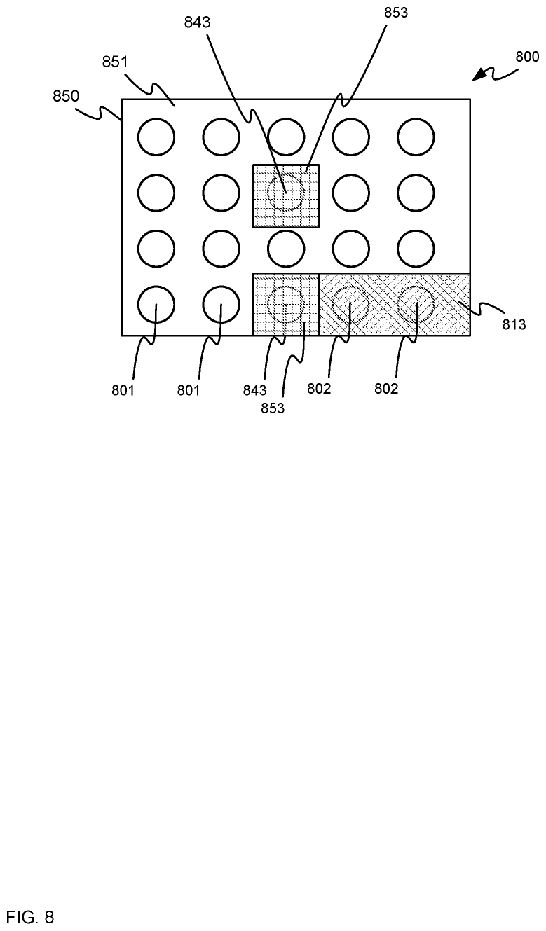

For example, attention is directed to FIG. 8 which, is similar to FIG. 6, with like components having like numbers, but in an “800” series rather than a “500” series. In particular, FIG. 8 depicts a top view of a laser diode array 800 (interchangeably referred to hereafter as the array 800) having a similar structure to the array 500, and including laser diode devices 801, 802, respectively similar to the laser diode devices 501, 502, and which emit light, respectively, at a first wavelength and a second wavelength respectively similar to the wavelengths 511, 512. The laser diode devices 802 include a notch filter 813 as described below, but generally similar to the notch filter 513. While not all components of the array 800 are depicted, the array 800 is understood to have a similar structure as the array 500 as depicted in FIG. 5.

However, in contrast to the array 500, the array 800 further includes laser diode devices 843 that emit light at a third wavelength different from each of the wavelengths emitted by the laser diode devices 801, 802. Indeed, laser diode devices 801 may comprise free-running laser diodes, while each of the laser diode devices 802, 843 may comprise WSOF laser diodes, similar to the laser diode devices 502, but emitting light at different wavelengths. Hence, the array 800 may emit light at wavelengths similar to the array 700.

The notch filter 813 of the second subset of the laser diode devices 802, and a respective notch filter 853 of the third subset of the laser diode devices 843 are located at a common window 850 located adjacent respective package windows of the laser diode devices 802, 843 of the second subset and the third subset of the laser diode devices 802, 843.

The common window 850 comprises: a transparent region (or regions) 851 aligned with the respective package windows of the laser diode devices 801 of the first subset; a first notch filter region (or regions) aligned with the respective package windows of the laser diode devices 802 of the second subset, the first notch filter regions each including the notch filter 813; and a second notch filter region (or regions) aligned with the respective package windows of the laser diode devices 843 of the third subset, the second notch filter regions each including the respective notch filter 853.

In this specification, elements may be described as “configured to” perform one or more functions or “configured for” such functions. In general, an element that is configured to perform or configured for performing a function is enabled to perform the function, or is suitable for performing the function, or is adapted to perform the function, or is operable to perform the function, or is otherwise capable of performing the function.

It is understood that for the purpose of this specification, language of “at least one of X, Y, and Z” and “one or more of X, Y and Z” can be construed as X only, Y only, Z only, or any combination of two or more items X, Y, and Z (e.g., XYZ, XY, YZ, XZ, and the like). Similar logic can be applied for two or more items in any occurrence of “at least one . . . ” and “one or more . . . ” language.

The terms “about”, “substantially”, “essentially”, “approximately”, and the like, are defined as being “close to”, for example as understood by persons of skill in the art. In some embodiments, the terms are understood to be “within 10%,” in other embodiments, “within 5%”, in yet further embodiments, “within 1%”, and in yet further embodiments “within 0.5%”.

Persons skilled in the art will appreciate that in some embodiments, the functionality of devices and/or methods and/or processes described herein can be implemented using pre-programmed hardware or firmware elements (e.g., application specific integrated circuits (ASICs), electrically erasable programmable read-only memories (EEPROMs), etc.), or other related components. In other embodiments, the functionality of the devices and/or methods and/or processes described herein can be achieved using a computing apparatus that has access to a code memory (not shown) which stores computer-readable program code for operation of the computing apparatus. The computer-readable program code could be stored on a computer readable storage medium which is fixed, tangible and readable directly by these components, (e.g., removable diskette, CD-ROM, ROM, fixed disk, USB drive). Furthermore, it is appreciated that the computer-readable program can be stored as a computer program product comprising a computer usable medium. Further, a persistent storage device can comprise the computer readable program code. It is yet further appreciated that the computer-readable program code and/or computer usable medium can comprise a non-transitory computer-readable program code and/or non-transitory computer usable medium. Alternatively, the computer-readable program code could be stored remotely but transmittable to these components via a modem or other interface device connected to a network (including, without limitation, the Internet) over a transmission medium. The transmission medium can be either a non-mobile medium (e.g., optical and/or digital and/or analog communications lines) or a mobile medium (e.g., microwave, infrared, free-space optical or other transmission schemes) or a combination thereof.

Persons skilled in the art will appreciate that there are yet more alternative embodiments and modifications possible, and that the above examples are only illustrations of one or more embodiments. The scope, therefore, is only to be limited by the claims appended hereto.

1. A laser diode array for a projector comprising:
a first subset of laser diode devices configured to emit a first wavelength;
a second subset of the laser diode devices, wherein each of the laser diode devices of the first subset and the second subset are provided in separate respective packages, wherein each of the first subset and the second subset comprise a plurality of respective laser diode devices, each of the laser diode devices of the second subset comprising:
a wavelength selective optical feedback laser diode configured to emit according to a gain curve that includes the first wavelength; and
a notch filter configured to reflect a second wavelength of the gain curve into the wavelength selective optical feedback laser diode to cause the wavelength selective optical feedback laser diode to amplify the second wavelength, the second wavelength different from the first wavelength, wherein the notch filter of each of the laser diode devices of the second subset is located at respective package windows of the separate respective packages of the laser diode devices of the second subset;
an alignment component comprising comprise apertures through which the separate respective packages extend; and
a collimating lens array, each collimating lens of the collimating lens array configured to collimate light from a respective laser diode of the laser diode array such that the first wavelength from the first subset of the laser diode devices and the second wavelength from the second subset of the laser diode devices is directed by a respective collimating lens to collection optics configured to align light from the laser diode devices.

2. The laser diode array of claim 1, wherein the second wavelength is photopically shifted, relative to the first wavelength.

3. The laser diode array of claim 1, wherein a difference between the second wavelength and the first wavelength is in a range of about 1 nm to about 3 nm.

4. (canceled)

5. (canceled)

6. (canceled)

7. The laser diode array of claim 1, wherein the laser diode array further comprises a third subset of the laser diode devices also provided in the separate respective packages, each of the laser diode devices of the third subset comprising:
a respective wavelength selective optical feedback laser diode configured to emit according to a respective gain curve that includes the first wavelength; and
a respective notch filter configured to reflect a third wavelength of the respective gain curve into the respective wavelength selective optical feedback laser diode to cause the respective wavelength selective optical feedback laser diode to amplify the third wavelength, the third wavelength different from each of the first wavelength and the second wavelength, wherein the notch filter and the respective notch filter of the second subset and the third subset are located at the respective package windows of the separate respective packages of the laser diode devices of the second subset and the third subset, and the alignment component further comprises comprise respective apertures through which the separate respective packages of the third subset extend.

8. The laser diode array of claim 7, wherein the third wavelength is photopically shifted, relative to the first wavelength.

9. The laser diode array of claim 7, wherein a difference between the third wavelength and the first wavelength is in a range of about 1 nm to about 3 nm.

10. (canceled)

11. (canceled)

12. (canceled)

13. The laser diode array of claim 7, wherein each of the first subset, the second subset and the third subset each comprise one third of the laser diode devices of the laser diode array.

14. (canceled)
